(19) United States
(12) Patent Application Publication
(10) Pub. No.: US 2024/0020441 A1
(43) Pub. Date: Jan. 18, 2024

(54) ASSESSMENT METHOD AND DEVICE FOR SEISMIC LANDSLIDE HAZARD BASED ON LANDSLIDE-DENSITY-NEWMARK (LS-D-NEWMARK) MODEL, AND PROCESSING DEVICE

(71) Applicant: Institute of Geomechanics,Chinese Academy of Geological Sciences, Beijing (CN)

(72) Inventors: Changbao GUO, Beijing (CN); Caihong LI, Beijing (CN); Yongshuang ZHANG, Beijing (CN); Yiqiu YAN, Beijing (CN); Xujiao ZHANG, Beijing (CN); Zhihua YANG, Beijing (CN); Ruian WU, Beijing (CN)

(21) Appl. No.: 18/476,154

(22) Filed: Sep. 27, 2023

(51) Int. Cl. G06F 30/20

(52) U.S. Cl. CPC G06F 30/20

(57) ABSTRACT

An assessment method for seismic landslide hazard based on a LS-D-Newmark model is performed as follows. Historical landslide data is acquired, and a historical landslide density is determined. The historical landslide data is input into the LS-D-Newmark model, and model parameters are adjusted, such that a static safety factor Fₛ of a slope is greater than 1 in the absence of external forces. The historical landslide density is introduced to the LS-D-Newmark model, and assignment of the static safety factor Fₛ is optimized to obtain an optimized static safety factor F_{s-L}. A slope critical acceleration a_{c-L} and an earthquake-induced slope displacement D_{n-L}, are calculated to calculate a landslide occurrence probability P of a target landslide region. An assessment device, a processing device, and a computer-readable storage medium for implementing the method are further provided.

### TECHNICAL FIELD

This application relates to geohazard control engineering, and more particularly to an assessment method and device for seismic landslide hazard based on a landslide-density-Newmark (LS-D-Newmark) model, and a processing device.

### BACKGROUND

Seismic landslide is triggered by seismic action or seismic force, which is a geological phenomenon in which the rock or soil slope suddenly leaves the sliding source zone, and suffers instantaneous destabilization under the action of earthquake. The seismic landslide hazard is assessed according to the international landslide hazard assessment criteria. The earthquake is strictly taken as a potential uncertainty, and the spatial and temporal distribution probabilities of potential earthquakes and landslides triggered thereby are analyzed. The specific hazard description indexes include the position, volume (or area), landslide type, migration velocity, and the occurrence probability in a certain period of the potential seismic landslide. In view of this, the seismic landslide hazard is distinctly predictive and assessable.

The main model-based seismic landslide hazard assessment methods in the prior art are listed as follows.

1. Comprehensive Assessment Method Based on Statistical Analysis

In this method, the correlation between seismic landslide and seismological background is statistically analyzed to reveal the controlling effect of seismological background on the occurrence of landslide and explore the main controlling factors of seismic landslides. The multi-factor-based seismic landslide hazard assessment is completed through support vector machine, information value and logistic regression.

2. Quasi-Static Method Based on Limit Equilibrium Theory

The seismic force acting on the slope is decomposed along the sliding surface (or the maximum slope direction), and the ratio of the sliding force of the slope to anti-slide force under the action of earthquake is calculated to assess the landslide hazard.

3. Newmark Model Method Based on the Slope Cumulative Displacement

The slope displacement under the action of seismic loading is calculated to predict and assess the earthquake-induced landslide hazard.

It has been found in the existing research that the currently-adopted Newmark model, which can assess the seismic landslide hazard based on topographic slope, geotechnical mechanics parameters and peak ground acceleration (PGA), still struggles with unstable prediction accuracy.

### SUMMARY

In view of the deficiencies in the prior art, this application provides an assessment method and device for seismic landslide hazard based on a LS-D-Newmark model, and a processing device. In the assessment method provided herein, a historical landslide density factor is incorporated in the prediction of seismic landslide hazards using a Newmark model to further improve the prediction accuracy of seismic landslide hazards.

In a first aspect, this application provides an assessment method for seismic landslide hazard based on a LS-D-Newmark model, comprising:

acquiring historical landslide data;

determining a historical landslide density based on the historical landslide data;

inputting the historical landslide data into the LS-D-Newmark model; and adjusting parameters of the LS-D-Newmark model according to geotechnical mechanics parameters and slope geometry parameters, such that a static safety factor Fₛ of a slope is greater than 1 in the absence of an external force;

introducing the historical landslide density to the LS-D-Newmark model to incorporate a historical landslide factor; and optimizing assignment of the static safety factor Fₛ to obtain an optimized static safety factor F_{s-L};

calculating a slope critical acceleration a_{c-L} based on the optimized static safety factor F_{s-L};

calculating an earthquake-induced slope displacement D_{n-L}, based on the slope critical acceleration a_{c-L} and a peak ground acceleration (PGA); and

based on the earthquake-induced slope displacement D_{n-L}, calculating a landslide occurrence probability P of a target landslide region to complete a seismic landslide hazard assessment of the target landslide region.

In an embodiment, the step of “determining historical landslide density based on existing landslide database” comprises:

according to the historical landslide data, calculating the historical landslide density by using a kernel density estimation algorithm with a search radius of 5 km.

In an embodiment, in a process of adjusting the parameters of the LS-D-Newmark model, the static safety factor is expressed as:

$$Fs = \frac{{c}^{′}}{γ t sin α} + \frac{tan {φ}^{′}}{tan α} - \frac{m {γ}_{w} tan {φ}^{′}}{γ tan α} = \frac{{c}^{′}}{γ t sin α} + ( 1 - \frac{m {γ}_{w}}{γ} ) \times \frac{tan {φ}^{′}}{tan α} ;$$

wherein c′ is a cohesive force; γ is a unit weight of a rock mass; t is a thickness of a potential landslide mass; α is an inclination angle of a potential sliding surface; φ′ is an effective internal friction angle; m is a proportion of a thickness of a saturated portion of the potential landslide mass in the thickness of the potential landslide mass; and γ_{w} is a unit weight of groundwater.

The LS-D-Newmark model adds the existing landslide density factor on the basis of the Newmark model. Since areas with higher existing landslide density have lower slope stability, that is, the rock and soil parameters effective internal friction angle and cohesion. The value of the force parameter has been reduced. According to the degree of agreement between the prediction results and the actual landslide area and location, a reasonable value range for the regional rock and soil mass strength parameters is determined. The rock and soil mass parameters are optimized according to the existing landslide development density. Based on the optimization, the optimized static safety factor F_{s-L}, of the slope is obtained by calculating the mechanical parameters of the rock and soil. However, no deformation and sliding occurs in the historical earthquake landslide area without external force, so the optimized static safety factor F_{s-L}, is still greater than 1.

In an embodiment, an optimization formula adopted in a process of optimizing assignment of the static safety factor Fₛ is expressed as F_{S-L}:

$${F}_{S - L} = \frac{Δ {x}_{1 , 2 , 3 , … , n} {c}^{′}}{γ t sin α} + ( 1 - \frac{m {γ}_{w}}{γ} ) \times \frac{tan ( Δ {y}_{1 , 2 , 3 , … , n} {φ}^{′} )}{tan α} ;$$

wherein n is the historical landslide density classification; Δx_{1,2,3, . . . , n} is a cohesion reduction coefficient; Δy_{1,2,3, . . . , n} is an internal friction angle reduction coefficient; and Δx_{1,2,3, . . . , n} and Δy_{1,2,3, . . . , n} satisfy a following table:

| Density classification | 1 | 2 | 3 | 4 |
|---|---|---|---|---|
| Δx | 1 | 0.85 | 0.6 | 0.5 |
| Δy | 1 | 0.85 | 0.7 | 0.65 |

In an embodiment, a formula for calculating the slope critical acceleration a_{c-L}, is expressed as:

a_{c-L}=(F_{s-L}−1)g sin α;

wherein g is a gravitational acceleration; and α is an inclination angle of a potential sliding surface.

In an embodiment, a formula for calculating the earthquake-induced slope displacement D_{n-L}, is expressed as:

$$lg {D}_{n - L} = 0.215 + lg [ {( 1 - \frac{{a}_{c - L}}{PGA} )}^{2.341} {( \frac{{a}_{c - L}}{PGA} )}^{- 1.438} ] .$$

In an embodiment, a formula for calculating the landslide occurrence probability P is expressed as:

P=0.335[1−exp(−0.048D_{n-L}^{1.565})].

In a second aspect, this application provides an assessment device for seismic landslide hazard based on a LS-D-Newmark model, comprising:

an acquisition unit;

a determination unit;

an adjustment unit;

an optimization unit; and

a calculation unit;

wherein the acquisition unit is configured for acquiring historical landslide data;

the determination unit is configured for determining historical landslide density based on the historical landslide data;

the adjustment unit is configured for inputting the historical landslide density into the LS-D-Newmark model, and adjusting parameters of the LS-D-Newmark model according to geotechnical mechanics parameters and slope geometry parameters, such that a static safety factor Fₛ of a slope is greater than 1 in the absence of an external force;

the optimization unit is configured for introducing the historical landslide density to the LS-D-Newmark model to incorporate a historical landslide factor, and optimizing assignment of the static safety factor Fₛ to obtain an optimized static safety factor F_{s-L}; and

the calculation unit is used to calculate the slope critical acceleration a_{c-L} based on the optimized static safety factor F_{s-L}, added to the historical landslide density; calculating an earthquake-induced slope displacement D_{n-L}, based on the slope critical acceleration a_{c-L} and a peak ground acceleration (PGA); and calculating a landslide occurrence probability P of a target landslide region based on the earthquake-induced slope displacement D_{n-L} to complete a seismic landslide hazard assessment of the target landslide region.

In a third aspect, this application provides a processing device, comprising:

a processor; and

a memory;

wherein a computer program is stored in the memory; and the processor is configured to execute the computer program to implement the assessment method.

In a fourth aspect, this application provides a computer-readable storage medium, wherein a plurality of instructions are stored on the computer-readable storage medium; and the plurality of instructions are configured to be loaded by a processor to implement the assessment method.

This application has the following beneficial effects.

In this application, the Newmark model is optimized for the prediction of seismic landslide hazard. Specifically, a landslide-density-Newmark (LS-D-Newmark) model is established based on the Newmark model. Historical landslide density is based on historical landslide database. The historical landslide data is input into the LS-D-Newmark model, and the relevant model parameters are adjusted according to geotechnical mechanics parameters and slope geometry parameters, such that a static safety coefficient Fₛ of a slope is greater than 1 in the absence of external forces. The historical landslide density is introduced into the LS-D-Newmark model to incorporate the historical landslide factor, and the assignment of static safety factor Fₛ is optimized to obtain an optimized static safety factor F_{s-L}. A slope critical acceleration a_{c-L} is calculated based on the optimized static safety factor F_{s-L}. An earthquake-induced slope displacement D_{n-L}, is calculated based on the slope critical acceleration a_{c-L} and a peak ground acceleration (PGA). A landslide occurrence probability P of a target landslide region is calculated based on the earthquake-induced slope cumulative displacement D_{n-L}, thereby completing the landslide hazard assessment of the target landslide region.

Compared with the area without experiencing a seismic landslide, the geotechnical structure and stability of the historical landslide region are attenuated. In the assessment process, the historical landslide density is involved in the seismic landslide hazard evaluation as an influence factor, avoiding the occurrence of the situation that the existing historical landslide regions have a lower hazard level in the hazard assessment results. Compared with the traditional Newmark model, the LS-D-Newmark model-based assessment method has higher prediction accuracy for the seismic landslide hazard and better applicability.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In order to illustrate technical solutions in the embodiments of the present disclosure more clearly, the drawings required in the description of the embodiments will be briefly described below. Obviously, presented in the drawings are merely some embodiments of the present disclosure, which are not intended to limit the disclosure. For those skilled in the art, other drawings may also be obtained according to the drawings provided herein without paying creative efforts.

FIG. 1 is a flow chart of an assessment method for seismic landslide hazard based on a LS-D-Newmark model according to one embodiment of the present disclosure;

FIG. 2 schematically shows an application scenario of the assessment method according to one embodiment of the present disclosure;

FIG. 3 schematically illustrates a historical landslide density in the Xianshuihe fault zone according to one embodiment of the present disclosure;

FIG. 4 shows seismic landslide hazard zonation based on the LS-D-Newmark model;

FIG. 5a shows hazard zonation results obtained based on the Newmark model-based assessment method;

FIG. 5b shows hazard zonation results obtained based on the LS-D-Newmark model-based assessment method;

FIG. 6 is a schematic diagram of an assessment device for seismic landslide hazard based on LS-D-Newmark model according to one embodiment of the present disclosure;

and

FIG. 7 is a schematic diagram of processing equipment according to one embodiment of the present disclosure.

### DETAILED DESCRIPTION OF EMBODIMENTS

The technical solutions in the embodiments of the disclosure will be described in detail below in combination with the drawings. Obviously, described below are merely some embodiments of the disclosure, which are not intended to limit the disclosure. For those skilled in the art, other embodiments obtained based on these embodiments without paying creative efforts should fall within the scope of the disclosure defined by the appended claims.

In addition, the terms “first” and “second” are merely descriptive to distinguish similar objects, and cannot be understood as indicating or implying relative importance and sequence.

It should be noted the used terms “first” and “second” may be interchanged, where appropriate, so that the embodiments described herein can be implemented in an order other than what is illustrated or described herein. As used herein, the terms “include”, “comprise”, and any variations thereof, are intended to cover a non-exclusive inclusion, and indicate the presence of the described steps or modules in a process, method, system, product, or apparatus, but do not exclude the presence of other steps or modules that are not clearly listed or are inherent. The naming or numbering of the steps in the disclosure does not imply that the steps in the method or process must be performed in the chronological/logical order indicated by the naming or numbering. The steps of the process that have been named or numbered may be performed in a different order according to the technical purpose to be realized, as long as the same or similar technical effect can be achieved.

The modules in the disclosure are logically divided. There may be another division mode in practical applications, for example, a plurality of modules may be combined into or integrated into another system, or some features may be ignored or not implemented. Furthermore, the mutual coupling or direct coupling or communication connection shown or discussed may be achieved through some interfaces, and the indirect coupling or communication connection between modules may be electrical or other similar connections, none of which are limited in this disclosure. Moreover, the modules or sub-modules illustrated as separated components may or may not be physically separated, may or may not be physical modules, or may be distributed in a plurality of circuit modules, some or all of which may be selected as practically necessary to accomplish the purposes of the present disclosure.

The relevant background of the present disclosure will be described prior to the introduction of an assessment method provided herein for seismic landslide hazard based on a LS-D-Newmark model.

The LS-D-Newmark-based assessment method for seismic landslide hazard, and apparatus, and the computer-readable storage medium provided in the present disclosure can be applied to a processing device for introducing a historical landslide density factor in the Newmark model-based prediction of seismic landslide hazard, so as to further improve the prediction accuracy of seismic landslide hazards.

The LS-D-Newmark-based assessment method for seismic landslide hazard may be performed by an LS-D-Newmark-based assessment device for seismic landslide hazard, or different types of processing devices such as servers, physical hosts, or user equipment (UE) that are integrated with the LS-D-Newmark-based assessment device for seismic landslide hazard. Among them, the LS-D-Newmark-based assessment device for seismic landslide hazard can be realized by means of hardware or software. The UE can be a terminal device such as a smartphone, a tablet computer, a laptop computer, a desktop computer, or a Personal Digital Assistant (PDA). The processing device can be set up by means of a cluster of equipment.

The assessment method for seismic landslide hazard based on a LS-D-Newmark model provided in the disclosure will be further described in detail.

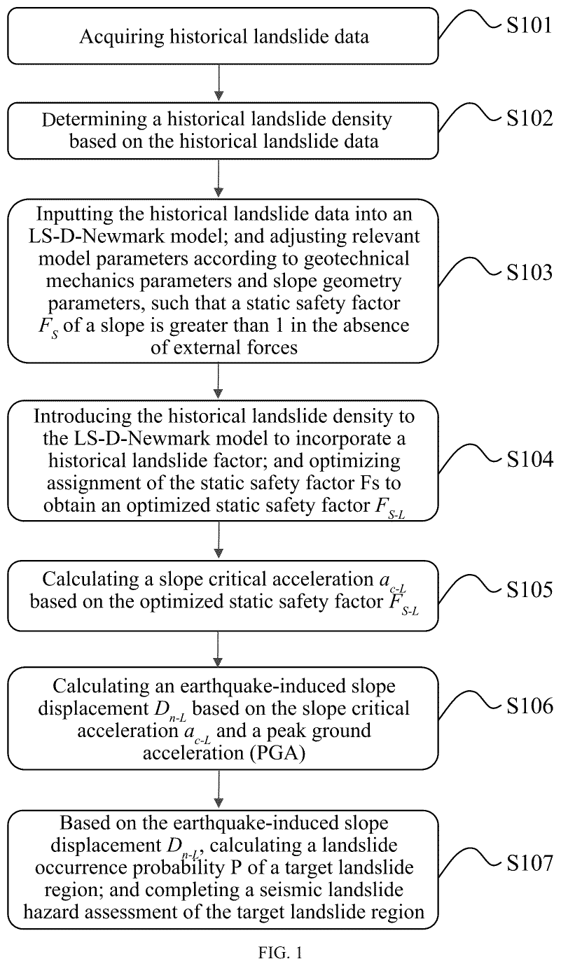

Referring to FIG. 1, FIG. 1 is a flow chart of an assessment method for seismic landslide hazard based on a LS-D-Newmark model in an embodiment. In this embodiment, the assessment method for seismic landslide hazard based on the LS-D-Newmark model include the following steps (S101)-(S107).

(S101) Acquisition of Historical Landslide Data

It is to be understood that the historical landslide data may be like the data content involved in the seismic landslide hazard assessment based on the Newmark model in the prior art. The optimized data processing made in the present disclosure are made based on the initial data, i.e., the historical landslide data.

Of course, in specific applications, the present disclosure may also involve further optimization of the data acquisition method or data content of the historical landslide data involved in the seismic landslide hazard assessment.

For example, in practical application, the historical landslide data may be extracted from a pre-established historical landslide database, which is easy to understand as a specialized log-in, storing historical landslide data of different regions for subsequent data calling.

The historical landslide database, as a practical implementation method, can be obtained from data sources in terms of remote sensing interpretation, historical data collection, or field investigation.

(S102) Based on the historical landslide data, a historical landslide density is determined.

It is to be understood that the Newmark model is optimized when performing the seismic landslide hazard assessment based on the Newmark model. That is, the seismic landslide hazard assessment is performed based on the equipped LS-D-Newmark model. The LS-D-Newmark model (i.e., Landslide-Density-Newmark model) is based on the Newmark model with the addition of the factor of historical landslide density (LS-D). Correspondingly, optimization settings are also made in the input parameters of the Newmark model, i.e., the historical landslide density factor involved here.

Correspondingly, based on the historical landslide data obtained earlier, the present disclosure can then determine the historical landslide density based on its directly described or potentially relevant geologic properties which require the data processing, to provide later data support.

In an embodiment, according to the historical landslide data, the historical landslide density can be calculated by using a kernel density estimation algorithm with a search radius of 5 km.

In an embodiment, the kernel density estimation algorithm is a pre-configured search algorithm for searching the historical landslide density.

It can be understood that in this disclosure, the kernel density estimation algorithm can be directly configured, or other algorithms are used, for example, the kernel density estimation algorithm in the spatial analysis of the ArcGIS software can be utilized, as long as the density search needs can be satisfied.

(S103) The historical landslide data is input into the LS-D-Newmark model. The parameters of the LS-D-Newmark model are adjusted according to geotechnical mechanics parameters and slope geometry parameters, such that a static safety factor Fₛ of a slope is greater than 1 in the absence of an external force.

It can be understood that for the adjustment of the parameters of the LS-D-Newmark model, the geotechnical mechanics parameters and the slope geometry parameters are utilized to be calculated in a plurality of loop iterations. The parameters of the LS-D-Newmark model are adjusted based on the Newmark model, which is used to provide an effective model parameter environment for the subsequent data processing, such that the static safety factor Fₛ of the slope is greater than 1 in the absence of external forces.

In an embodiment, in a process of adjusting the parameters of the LS-D-Newmark model, the static safety factor (the slope safety factor formula based on the Newmark model-based landslide limit equilibrium theory) is expressed as:

$$Fs = \frac{{c}^{′}}{γ t sin α} + \frac{tan {φ}^{′}}{tan α} - \frac{m {γ}_{w} tan {φ}^{′}}{γ tan α} = \frac{{c}^{′}}{γ t sin α} + ( 1 - \frac{m {γ}_{w}}{γ} ) \times \frac{tan {φ}^{′}}{tan α} .$$

In the above formula, c′ is a cohesive force (kPa); γ is a unit weight of a rock mass (kN/m³); t is a thickness of a potential landslide mass (m); α is an inclination angle)(° of a potential sliding surface; p′ is an effective internal friction angle)(°; m is a proportion of a thickness of a saturated portion of the potential landslide mass in the thickness of the potential landslide; and γ_{w} is a unit weight (kN/m³) of groundwater.

(S104) The historical landslide density is introduced to the LS-D-Newmark model to incorporate a historical landslide factor. The assignment of the static safety factor Fₛ is optimized to obtain the optimized static safety factor F_{s-L}.

As mentioned above, the optimized settings performed for the input parameters of the LS-D-Newmark model can be reflected in the historical landslide density factor.

At this point, the previously determined historical landslide density can be brought into the LS-D-Newmark model with optimized model parameters. In the model, the assignment of the static safety factor Fₛ is optimized based on the input historical landslide density.

Specifically, due to the lower stability of the historical landslide region compared to the non-historical landslide region, the static safety factor Fₛ of the historical landslide region is lower, but the historical landslide region has not deformed and slid in the absence of the external force, so the static safety factor Fₛ is still greater than 1. Under this circumstance, the present disclosure optimizes the static safety factor Fₛ, adds the historical landslide density factor, and optimizes the assignment of the static safety factor Fₛ to obtain the optimized static safety factor F_{s-L}, to differentiate the calculation of the optimized static safety factor F_{s-L} between the historical landslide regions and non-historic landslide regions. In this way, the seismic landslide regions and non-historical landslide regions are more clearly subdivided in the model, so that the subsequent seismic landslide hazard evaluation can be handled in a more detailed manner.

In an embodiment, an optimization formula adopted in a process of optimizing assignment of the static safety factor Fₛ is expressed as:

$${F}_{S - L} = \frac{Δ {x}_{1 , 2 , 3 , … , n} {c}^{′}}{γ t sin α} + ( 1 - \frac{m {γ}_{w}}{γ} ) \times \frac{tan ( Δ {y}_{1 , 2 , 3 , … , n} {φ}^{′}}{tan α} ;$$

wherein n is the historical landslide density classification; Δx_{1,2,3, . . . , n} is the cohesion reduction coefficient; Δy_{1,2,3, . . . , n} is the internal friction angle reduction coefficient.

| Density classification | 1 | 2 | 3 | 4 |
|---|---|---|---|---|
| Δx | 1 | 0.85 | 0.6 | 0.5 |
| Δy | 1 | 0.85 | 0.7 | 0.65 |

It can be understood that this landing solution proposed by the present disclosure to optimize the static safety factor Fₛ is based on the historical landslide density factor.

(S105) A slope critical acceleration a_{c-L} is calculated based on the optimized static safety factor F_{s-L}.

After obtaining the optimized static safety factor F_{s-L} and completing a more explicit and clearer subdivision of the landslide region and the non-historical landslide region in the model, the slope critical acceleration a_{c-L} can be continued to be calculated. The slope critical acceleration a_{c-L} can be understood as the seismic acceleration under the action of the seismic loading when the downward sliding force of the landslide is equal to the anti-slide force which is the state of limiting equilibrium.

In an embodiment, the present disclosure establishes an equation for the limit equilibrium state of the landslide under seismic action by comparing the force state of the landslide under static and seismic force conditions. In the process of calculating the slope critical acceleration a_{c-L}, the formula for calculating the slope critical acceleration a_{c-L} is expressed as:

a_{c-L}=(F_{s-L}−1)g sin α.

In above formula, g is a gravitational acceleration (m/s²); and α is an inclination angle (°) of a potential sliding surface.

(S106) An earthquake-induced slope displacement D_{n-L} is calculated based on the slope critical acceleration a_{c-L} and the known peak ground acceleration (PGA). After obtaining the slope critical acceleration a_{c-L}, the earthquake-induced slope displacement D_{n-L} can be continued to be calculated. Thus, the earthquake-induced slope displacement D_{n-L} herein also distinguishes between the landslide region and the non-historical landslide region.

The known peak ground acceleration (PGA) is public and generalized data. For example, in practical application, the PGA data in the “Seismic peak ground acceleration zonation map of China” (GB18306-2015) with the 50-year exceeding probability of 10% can be used.

In addition, by statistically analyzing many seismic acceleration records and examples of seismic landslides, the present disclosure obtains a functional relationship formula for the earthquake-induced slope displacement D_{n-L}, the slope critical acceleration a_{c-L}, and the PGA. In an embodiment, a calculation formula for the earthquake-induced slope displacement D_{n-L} is expressed as:

$${lgD}_{n - L} = 0.215 + lg [ {( 1 - \frac{{a}_{c - L}}{PGA} )}^{2.341} {( \frac{{a}_{c - L}}{PGA} )}^{- 1.438} ] .$$

It can also be obtained that in the landing solution herein, the slope cumulative displacement D_{n-L} is directly proportional to the PGA and inversely proportional to the slope critical acceleration a_{c-L}.

(S107) Based on the earthquake-induced slope displacement D_{n-L}, a landslide occurrence probability P of a target landslide region is calculated to complete a seismic landslide hazard assessment of the target landslide region.

After obtaining the earthquake-induced slope displacement D_{n-L}, the corresponding landslide occurrence probability P can be determined based on the correspondence between the induced slope cumulative displacement and the landslide occurrence probability P, as the result of the seismic landslide hazard assessment of the target landslide region.

In an embodiment, the present disclosure also provides a landing solution for calculating the landslide occurrence probability P. In the process of calculating the landslide occurrence probability P of the target landslide region, the formula for calculating the landslide occurrence probability P is expressed as:

P=0.335[1−exp(−0.048D_{n-L}^{1.565})].

Further, based on the landslide occurrence probability P as the result of the seismic landslide hazard assessment, the present disclosure may also involve a partitioning treatment of the hazards. Specifically, according to the landslide occurrence probability P of the different target seismic landslide regions, the overall seismic landslide region is partitioned into seismic landslide hazard region, thereby delineating the areas with different seismic landslide hazards.

More detailed data guidance can be provided for practical applications.

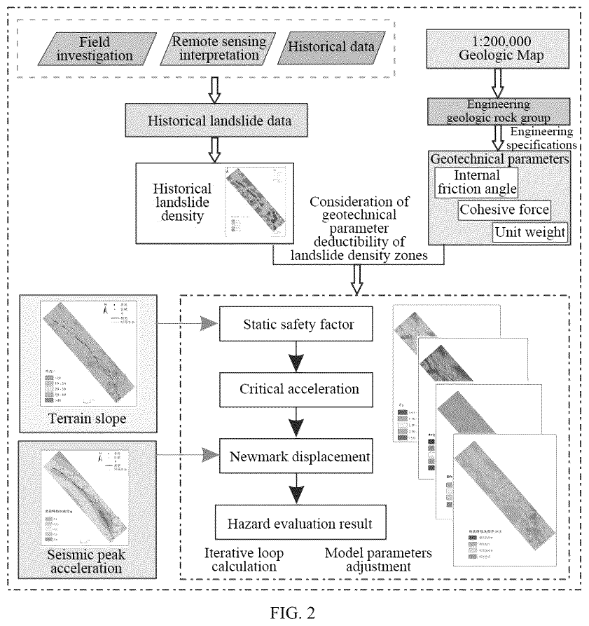

In order to further understand the contents of the above solution (including the contents of each embodiment), a deeper understanding could also be provided by an application scenario of the assessment method for seismic landslide hazard based on the LS-D-Newmark model shown in FIG. 2.

Taking about 20 km on both sides of the Xianshuihe fault zone in Sichuan Province as the study area, the present disclosure performed seismic landslide hazard assessment by means of the assessment method for seismic landslide hazard based on the LS-D-Newmark model. Specifically, the assessment method for seismic landslide hazard based on the LS-D-Newmark model was completed by adding the historical landslide density factor based on Newmark model, which mainly includes the following processing steps.

A historical landslide database in the Xianshuihe fault zone was established through remote sensing interpretation, historical data collection and field site investigation.

According to the established historical landslide database of the Xianshuihe fault zone, the kernel density estimation algorithm in the spatial analysis of ArcGIS software had a search radius of 5 km and was used to obtain the historical landslide density in the Xianshuihe fault zone (sites/km²). The seismic landslides in the study area were mainly distributed in a band along the Xianshuihe fault zone, in which the historical landslide density could reach the maximum of 20.18 sites/km².

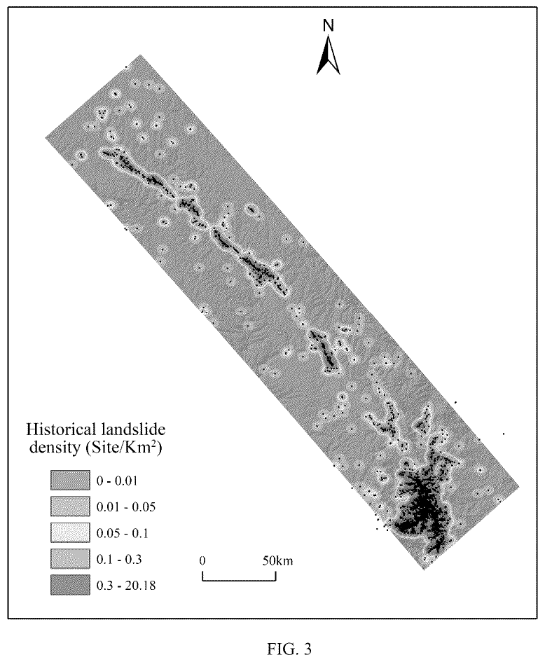

In this embodiment, the historical landslide density in the Xianshuihe fault zone could be referred to the schematic diagram of historical landslide density in the Xianshuihe fault zone shown in FIG. 3.

The topographic slope of the Xianshuihe fault zone was obtained based on topographic data.

Considering the factors of geological structure, stratigraphic age, type of rock-soil body, and degree of weathering and fragmentation of the rock body, the geological engineering rock formation in the study area was divided.

Physical and mechanical parameters of the geological engineering rock formations were shown in the comprehensive initialized representation according to the Geological Engineering Handbook (Fifth Edition).

| | | c′/ | (ϕ′/ | γ/ |
|---|---|---|---|---|
| ID | Geological engineering rock group | (kPa) | (°) | (kN/m³) |
| 1 | Hard thick layered sandstone group | 26 | 33 | 26 |
| 2 | Hard-harder medium-thick | 25 | 32 | 25 |
| | conglomerate-bearing layered | | | |
| | sandstone, mudstone, and slate group | | | |
| 3 | Soft-hard medium-thick layered | 25 | 32 | 24 |
| | sandstone, mudstone with | | | |
| | limestone, argillaceous limestone, | | | |
| | and interstratified rock group | | | |
| 4 | Soft-hard thin-medium-thick layered | 20 | 27 | 23 |
| | sandstone, mudstone and | | | |
| | conglomerate, mudstone-interbedded | | | |
| | rock group | | | |
| 5 | Soft thin-bedded mudstone and | 24 | 31 | 21 |
| | shale group | | | |
| 6 | Hard medium-thick-bedded | 23 | 31 | 25 |
| | limestone and dolomite group | | | |
| 7 | Hard thin-medium-thick-bedded | 23 | 30 | 24 |
| | limestone, argillaceous limestone | | | |
| | group | | | |
| 8 | Soft-hard medium-thick-bedded | 22 | 29 | 23 |
| | limestone, dolomite with sand, | | | |
| | mudstone, phyllite, slate group | | | |
| 9 | Hard-harder thin-medium-thick-bedded | 21 | 28 | 22 |
| | slate, dolomite and metasandstone | | | |
| | interbedded rock group | | | |
| 10 | Soft-hard thin-medium-thick-bedded | 28 | 35 | 21 |
| | phyllite, schist with limestone, | | | |
| | sandstone, and volcanic rock group | | | |
| 11 | Hard massive basalt-dominated | 27 | 34 | 29 |
| | rock group | | | |
| 12 | Hard massive granite, andesite, | 19 | 26 | 28 |
| | diorite rock group | | | |
| 13 | Soft loose structural rock groups | 15 | 25 | 18 |

Note:
c′ is the cohesive force;
′φ is the effective internal friction angle; and
γ is the unit weight of the rock mass.

According to the slope safety coefficient formula (1) based on the landslide limit equilibrium theory, the static safety factor Fₛ of the slope is calculated by the geotechnical mechanics parameters and the geometry parameters of the slope. The slope has not deformed and slid in the absence of the external force, so the static safety factor Fₛ is greater than 1.

$$Fs = \frac{{c}^{′}}{γ t sin α} + \frac{tan {φ}^{′}}{tan α} - \frac{m {γ}_{w} tan {φ}^{′}}{γ tan α} = \frac{{c}^{′}}{γ t sin α} + ( 1 - \frac{m {γ}_{w}}{γ} ) \times \frac{tan {φ}^{′}}{tan α} . \qquad ( 1 )$$

Due to the lower seismic landslide stability in the historical landslide region, the static safety factor Fₛ is lower. But no deformation and sliding are occurred in the historical landslide region without external force, so the static safety factor Fₛ in the historical landslide region is still greater than 1. The formula of the static safety factor F_{s-L}, is optimized and adjusted to add the historical landslide density factor to differentiate the historical landslide region and the non-historical landslide region in the calculation of the static safety factor F_{s-L}.

The addition of the historical landslide density factor avoids the higher stability or lower earthquake-induced landslide hazard in the historical landslide regions, and an optimization formula (2) adopted in a process of optimizing assignment of the static safety factor Fₛ is expressed as:

$${Fs}_{- L} = \frac{Δ {x}_{1 , 2 , 3 , … , n} c}{γ t sin α} + ( 1 - \frac{m {γ}_{w}}{γ} ) \times \frac{tan ( Δ {y}_{1 , 2 , 3 , … , n} {φ}^{′} )}{tan α} . \qquad ( 2 )$$

n is the seismic landslide density classification; Δx_{1,2,3, . . . , n} is the cohesion cohesion reduction coefficient; Δy_{1,2,3, . . . , n} is Internal friction angle reduction coefficient.

| Density classification | 1 | 2 | 3 | 4 |
|---|---|---|---|---|
| Δx | 1 | 0.85 | 0.6 | 0.5 |
| Δy | 1 | 0.85 | 0.7 | 0.65 |

By comparing the force state of the landslide under static and seismic force conditions, the equation for the limit equilibrium state of the landslide under seismic action can be established. The formula for calculating the slope critical acceleration a_{c-L} (formula (3) can be derived by the optimized static safety factor F_{s-L}, (obtained from formula (2)).

a_{c-L}=(F_{s-L}−1)g sin α (3)

The slope critical acceleration a_{c-L} in the study region is calculated by formula (3). By statistically analyzing many seismic acceleration records and examples of seismic landslides, the functional relationship formula (4) for the earthquake-induced slope cumulative displacement D_{n-L}, the slope critical acceleration a_{c-L}, and the PGA is established.

The zonation value in the “seismic peak ground acceleration zonation map of China” (GB18306-2015) with the 50-year exceeding probability of 10% can be used to calculate the earthquake-induced slope displacement D_{n-L}.

$${lgD}_{n - L} = 0.215 + lg [ {( 1 - \frac{{a}_{c - L}}{PGA} )}^{2.341} {( \frac{{a}_{c} - L}{PGA} )}^{- 1.438} ] . \qquad ( 4 )$$

The landslide occurrence probability P under seismic action is calculated based on the correlation formula (5) between the seismic slope displacement D_{n-L} and the landslide occurrence probability P.

P=0.335[1−exp(−0.048D_{n-L}^{1.565})] (5)

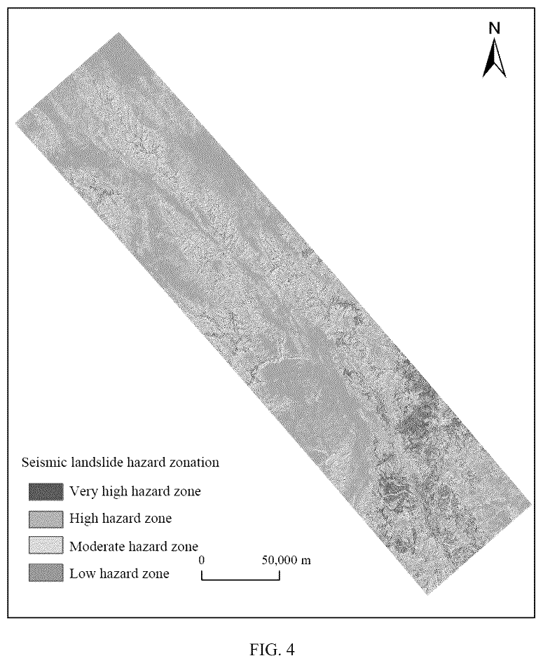

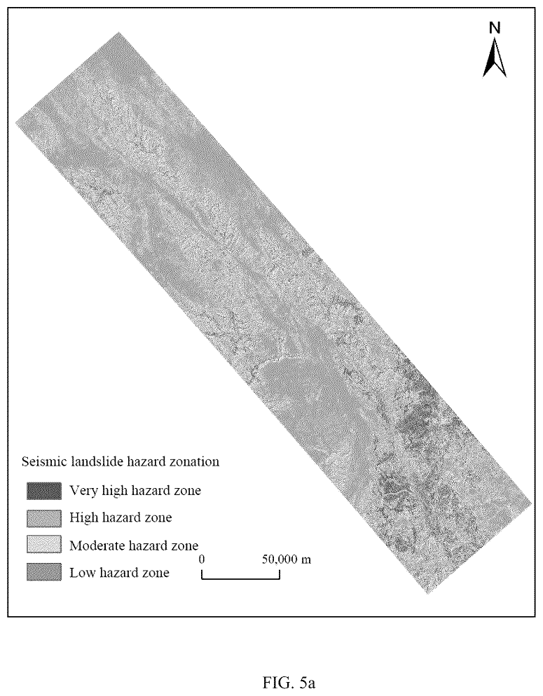

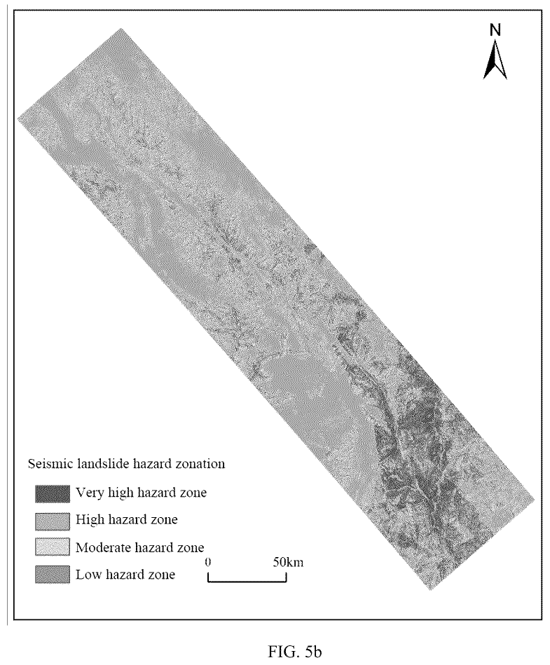

The seismic landslide hazard assessment of the Xianshuihe fault zone is completed based on the LS-D-Newmark model. The zonation results of the seismic landslide hazard assessment of the Xianshuihe fault zone are illustrated in FIG. 4. Compared with the traditional Newmark model, FIG. 5a shows hazard zonation results obtained based on the Newmark model-based assessment method. FIG. 5b shows hazard zonation results obtained based on the LS-D-Newmark model-based assessment method.

In general, in this disclosure, the Newmark model is optimized for the prediction of seismic landslide hazard. Specifically, a landslide-density-Newmark (LS-D-Newmark) model is established based on the Newmark model. After acquiring historical landslide data, a historical landslide density is determined based on the historical landslide data. The historical landslide data is input into the LS-D-Newmark model, and the relevant model parameters are adjusted according to geotechnical mechanics parameters and slope geometry parameters, such that a static safety coefficient Fₛ of a slope is greater than 1 in the absence of external forces. The historical landslide density is introduced into the LS-D-Newmark model to incorporate the historical landslide factor, and the assignment of static safety factor Fₛ is optimized to obtain the optimized static safety factor F_{s-L}. A slope critical acceleration a_{c-L} is calculated based on the optimized static safety factor F_{s-L}. An earthquake-induced slope displacement D_{n-L}, is calculated based on the slope critical acceleration a_{c-L} and a peak ground acceleration (PGA). A landslide occurrence probability P of a target landslide region is calculated based on the earthquake-induced slope cumulative displacement D_{n-L}, thereby completing the seismic landslide hazard assessment of the target landslide region.

Compared with the area without experiencing a seismic landslide, the geotechnical structure and stability of the historical landslide region are attenuated. In the assessment process, the historical landslide density is involved in the seismic landslide hazard evaluation as an influence factor, avoiding the occurrence of the situation that the existing historical landslide regions have a lower hazard level in the hazard assessment results. Compared with the traditional Newmark model, the LS-D-Newmark model-based assessment method has higher prediction accuracy for the seismic landslide hazard and better applicability.

The above is a description of the assessment method for seismic landslide hazard based on the LS-D-Newmark model provided by the present disclosure. To facilitate better implementation of the assessment method, the present disclosure also provides an assessment device for seismic landslide hazard based on the LS-D-Newmark model from the perspective of a functional module.

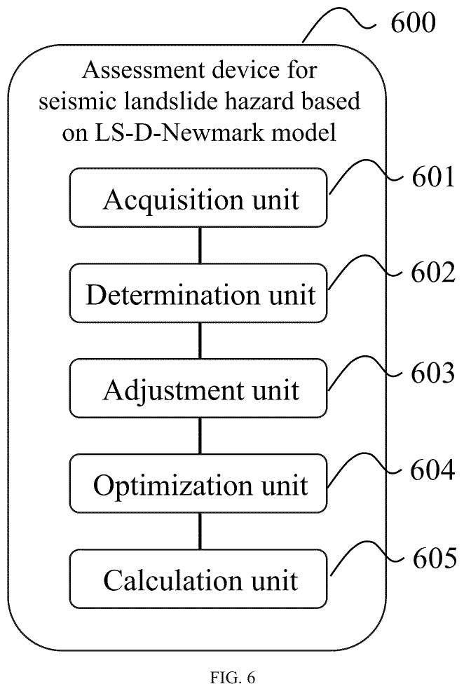

As shown in FIG. 6, the LS-D-Newmark model-based seismic landslide hazard assessment device includes an acquisition unit 601, a determination unit 602, an adjustment unit 603, an optimization unit 604, and a calculation unit 605.

The acquisition unit 601 is configured for acquiring historical landslide data.

The determination unit 602 is configured for determining the historical landslide density based on the historical landslide data.

The adjustment unit 603 is configured for inputting the historical landslide data into the LS-D-Newmark model, and adjusting the parameters of the LS-D-Newmark model according to geotechnical mechanics parameters and slope geometry parameters, such that the static safety factor Fₛ of the slope is greater than 1 in the absence of external forces.

The optimization unit 604 is configured for introducing the historical landslide density to the LS-D-Newmark model to incorporate the historical landslide factor, and optimizing assignment of the static safety factor Fₛ to obtain an optimized static safety factor F_{s-L}.

The calculation unit 605 is configured for calculating the slope critical acceleration a_{c-L} based on the optimized static safety factor F_{s-L}; calculating the earthquake-induced slope displacement D_{n-L} based on the slope critical acceleration a_{c-L} and the PGA; and calculating a landslide occurrence probability P of a target landslide region based on the earthquake-induced slope displacement D_{n-L}, to complete a seismic landslide hazard assessment of the target landslide region.

In an embodiment, the determination unit is used to calculating the historical landslide density by using a kernel density estimation algorithm with a search radius of km according to the seismic landslide data.

In an embodiment, in a process of adjusting the parameters of the LS-D-Newmark model, the static safety factor is expressed as:

$$Fs = \frac{{c}^{′}}{γ t sin α} + \frac{tan {φ}^{′}}{tan α} - \frac{m {γ}_{w} tan {φ}^{′}}{γ tan α} = \frac{{c}^{′}}{γ t sin α} + ( 1 - \frac{m {γ}_{w}}{γ} ) \times \frac{tan {φ}^{′}}{tan α} .$$

In the above formula, c′ is a cohesive force; γ is a unit weight of a rock mass; t is a thickness of a potential landslide mass; α is an inclination angle of a potential sliding surface; φ′ is an effective internal friction angle; m is a proportion of a thickness of a saturated portion of the potential landslide mass in the thickness of the potential landslide mass; and γ_{w} is a unit weight of groundwater.

In an embodiment, an optimization formula adopted in a process of optimizing assignment of the static safety factor Fₛ is expressed as:

$${F}_{S - L} = \frac{Δ {x}_{1 , 2 , 3 , … , n} {c}^{′}}{γ t sin α} + ( 1 - \frac{m {γ}_{w}}{γ} ) \times \frac{tan ( Δ {y}_{1 , 2 , 3 , … , n} {φ}^{′} )}{tan α} .$$

n is the historical landslide density classification; Δx_{1,2,3, . . . , n} is the cohesion reduction coefficient; and Δy_{1,2,3, . . . , n} is the internal friction angle reduction coefficient.

| Density classification | 1 | 2 | 3 | 4 |
|---|---|---|---|---|
| Δx | 1 | 0.85 | 0.6 | 0.5 |
| Δy | 1 | 0.85 | 0.7 | 0.65 |

In an embodiment, a formula for calculating the slope critical acceleration a_{c-L} is expressed as:

a_{c-L}=(F_{s-L}−1)g sin α.

In above formula, g is the gravitational acceleration; and a is the inclination angle of the potential sliding surface.

In an embodiment, a formula for calculating the earthquake-induced slope displacement D_{n-L} is expressed as:

$$lg {D}_{n - L} = 0.215 + lg [ {( 1 - \frac{{a}_{c - L}}{PGA} )}^{2.341} {( \frac{{a}_{c - L}}{PGA} )}^{- 1.438} ] .$$

In an embodiment, the formula for calculating the landslide occurrence probability P is expressed as:

P=0.335[1−exp(−0.048D_{n-L}^{1.565})].

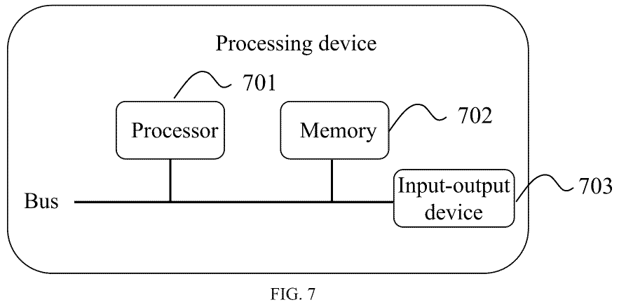

In terms of the hardware structure, the disclosure also provides a processing device as shown in FIG. 7. The processing device may include a processor 701, a memory 702, and an input-output device 703. The processor 701 is used to execute the computer programs stored in the memory 702 to implement the steps of the LS-D-Newmark model-based assessment method for seismic landslide hazard as in the embodiment shown in FIG. 1. Alternatively, the processor 701 is used, in executing the computer programs stored in the memory 702, to realize the functions of the units as in the embodiment shown in FIG. 6. The memory 702 is used to store the computer programs required by the processor 701 to execute the LS-D-Newmark model-based assessment method for seismic landslide hazard in the embodiment shown in FIG. 1 as described above.

In an embodiment, the computer programs may be divided into one or more modules/units. The one or more modules/units are stored in the memory 702 and executed by the processor 701 to complete the present disclosure. The one or more modules/units may be a series of computer program instruction segments capable of accomplishing a particular function. The instruction segments are used to describe the execution process of the computer program in the computer device.

The processing device may include, but is not limited to, the processor 701, the memory 702, and the input-output device 703. Those skilled in the art may understand that described above are merely embodiments of the processing device and do not intend to limit the processing device. The processing device may include more or fewer components than illustrated, or a combination of certain components, or different components. For example, the processing device may also include a network access device, a bus, and the like. The processor 701, the memory 702, and the input-output devices 703 are connected via the bus.

The processor 701 may be a Central Processing Unit (CPU), or may be another general-purpose processor, Digital Signal Processor (DSP), Application Specific Integrated Circuit (ASIC), Field-Programmable Gate Array (FPGA) or other programmable logic devices, discrete gate or transistor logic devices, discrete hardware components, and the like. The general-purpose processor can be the microprocessor, or the processor can be any conventional processor. The processor is the control center of the processing equipment, using various interfaces and lines to connect various parts of the entire equipment.

The memory 702 may be used to store computer programs and/or modules. The processor 701 implements various functions of the computer device by running or executing the computer programs and/or modules stored in the memory 702, and by calling up data stored in the memory 702. The memory 702 may primarily include a storage program area and a storage data area. The storage program area may store an operating system and an application program required for at least one function. The storage data area may store data created based on the use of the processing device. In addition, the memory may include a high-speed random access memory, and may also include a non-volatile memory, such as a hard disk, a memory, a plug-in hard disk, a Smart Media Card (SMC), a Secure Digital (SD) card, a Flash Card, at least one disk memory device, a flash memory device, or other volatile solid-state memory device.

When used to execute the computer program stored in the memory 702, the processor 701 may specifically perform the following functions: acquiring historical landslide; determining a historical landslide density o based on the seismic landslide data; inputting the historical landslide data into the LS-D-Newmark model; and adjusting parameters of the LS-D-Newmark model according to geotechnical mechanics parameters and slope geometry parameters, such that a static safety factor Fₛ of a slope is greater than 1 in the absence of an external force; introducing the historical landslide density to the LS-D-Newmark model to incorporate a historical landslide factor; and optimizing assignment of the static safety factor Fₛ to obtain an optimized static safety factor F_{s-L}; calculating a slope critical acceleration a_{c-L} based on the static safety factor F_{s-L} after optimized assignment; calculating an earthquake-induced slope displacement D_{n-L} based on the slope critical acceleration a_{c-L} and a peak ground acceleration (PGA); and based on the earthquake-induced slope displacement D_{n-L}, calculating a landslide occurrence probability P of a target landslide region to complete a seismic landslide hazard assessment of the target landslide region.

It can be understood by those skilled in the art that, for the convenience and conciseness of the description, the specific working process of the LS-D-Newmark model-based assessment device for seismic landslide hazard, the processing device and the corresponding unit thereof described above can be referred to as illustrated in the assessment method in the embodiment shown in FIG. 1. The specific steps of the method will not be repeated herein.

It can be understood by those skilled in the art that all or some of the steps in the various methods of the above embodiments may be accomplished by instructions, or by controlling the relevant hardware by instructions, which may be stored in a computer-readable storage medium and loaded and executed by a processor.

The present disclosure further provides a computer-readable storage medium in which a plurality of instructions is stored. The instructions can be loaded by the processor to execute the steps of the LS-D-Newmark model-based assessment method for seismic landslide hazard in the embodiment shown in FIG. 1. The specific steps of the assessment method will not be repeated herein.

The computer-readable storage medium may include a read only memory (ROM), a random access memory (RAM), a disk or a CD-ROM.

The instructions stored in the computer-readable storage medium can execute the steps of the assessment method for seismic landslide hazard based on the LS-D-Newmark model in the embodiment shown in FIG. 1. Thus, the beneficial effects that can be realized by the assessment method for seismic landslide hazard based on the LS-D-Newmark model in the embodiment shown in FIG. 1 can be achieved, which will not be repeated herein.

The seismic landslide hazard assessment method and device, processing device, and computer-readable storage medium provided in this disclosure have been described in detail above. Described above are merely preferred embodiments of the disclosure, which are not intended to limit the disclosure. It should be understood that any modifications and replacements made by those skilled in the art without departing from the spirit of the disclosure should fall within the scope of the disclosure defined by the appended claims.

What is claimed is:

1. An assessment method for seismic landslide hazard based on a LS-D-Newmark model, comprising:
acquiring historical landslide data;
determining a historical landslide density based on the historical landslide data;
inputting the historical landslide data into the LS-D-Newmark model; and adjusting parameters of the LS-D-Newmark model according to geotechnical mechanics parameters and slope geometry parameters, such that a static safety factor Fₛ of a slope is greater than 1 in the absence of an external force;
introducing the historical landslide density to the LS-D-Newmark model to incorporate a historical landslide factor; and optimizing assignment of the static safety factor Fₛ to obtain an optimized static safety factor F_{s-L};
calculating a slope critical acceleration a_{c-L} based on the optimized static safety factor F_{s-L};
calculating an earthquake-induced slope displacement D_{n-L}, based on the slope critical acceleration a_{c-L} and a peak ground acceleration (PGA); and
based on the earthquake-induced slope displacement D_{n-L}, calculating a landslide occurrence probability P of a target landslide region to complete a seismic landslide hazard assessment of the target landslide region.

2. The assessment method of claim 1, wherein the step of “determining a historical landslide density based on the historical landslide data” comprises:
according to the historical landslide data, calculating the historical landslide density by using a kernel density estimation algorithm with a search radius of 5 km.

3. The assessment method of claim 1, wherein in a process of adjusting the parameters of the LS-D-Newmark model, the static safety factor is expressed as:
$$Fs = \frac{{c}^{′}}{γ t sin α} + \frac{tan {φ}^{′}}{tan α} - \frac{m {γ}_{w} tan {φ}^{′}}{γ tan α} = \frac{{c}^{′}}{γ t sin α} + ( 1 - \frac{m {γ}_{w}}{γ} ) \times \frac{tan {φ}^{′}}{tan α} ;$$
wherein c′ is a cohesive force; γ is a unit weight of a rock mass; t is a thickness of a potential landslide mass; α is an inclination angle of a potential sliding surface; φ′ is an effective internal friction angle; m is a proportion of a thickness of a saturated portion of the potential landslide mass in the thickness of the potential landslide mass; and γ_{w} is a unit weight of groundwater.

4. The assessment method of claim 1, wherein an optimization formula adopted in a process of optimizing assignment of the static safety factor Fₛ is expressed as:
$${F}_{S - L} = \frac{Δ {x}_{1 , 2 , 3 , … , n} {c}^{′}}{γ t sin α} + ( 1 - \frac{m {γ}_{w}}{γ} ) \times \frac{tan ( Δ {y}_{1 , 2 , 3 , … , n} {φ}^{′} )}{tan α} .$$
wherein n is a historical landslide density classification; Δx_{1,2,3, . . . , n} is a cohesion reduction coefficient; and Δy_{1,2,3, . . . , n} is an internal friction angle reduction coefficient; and the Δx_{1,2,3, . . . , n} and Δy_{1,2,3, . . . , n} angle satisfy the following table:

| Density classification | 1 | 2 | 3 | 4 |
|---|---|---|---|---|
| Δx | 1 | 0.85 | 0.6 | 0.5 |
| Δy | 1 | 0.85 | 0.7 | 0.65 |

5. The assessment method of claim 1, wherein a formula for calculating the slope critical acceleration a_{c-L} is expressed as:
a_{c-L}=(F_{s-L}−1)g sin α;
wherein g is a gravitational acceleration; and α is an inclination angle of a potential sliding surface.

6. The assessment method of claim 1, wherein a formula for calculating the earthquake-induced slope displacement D_{n-L} is expressed as:
$$lg {D}_{n - L} = 0.215 + lg [ {( 1 - \frac{{a}_{c - L}}{PGA} )}^{2.341} {( \frac{{a}_{c - L}}{PGA} )}^{- 1.438} ] .$$

7. The assessment method of claim 1, wherein a formula for calculating the landslide occurrence probability P is expressed as:
P=0.335[1−exp(−0.048D_{n-L}^{1.565})].

8. An assessment device for seismic landslide hazard based on a LS-D-Newmark model, comprising:
an acquisition unit;
a determination unit;
an adjustment unit;
an optimization unit; and
a calculation unit;
wherein the acquisition unit is configured for acquiring historical landslide data;
the determination unit is configured for determining a historical landslide density based on the historical landslide data;
the adjustment unit is configured for inputting the historical landslide data into the LS-D-Newmark model, and adjusting parameters of the LS-D-Newmark model according to geotechnical mechanics parameters and slope geometry parameters, such that a static safety factor Fₛ of a slope is greater than 1 in the absence of an external force;
the optimization unit is configured for introducing the historical landslide density to the LS-D-Newmark model to incorporate a historical landslide factor, and optimizing assignment of the static safety factor Fₛ to obtain an optimized static safety factor F_{s-L}; and
the calculation unit is configured for calculating a slope critical acceleration a_{c-L} based on the optimized static safety factor F S-L; calculating an earthquake-induced slope displacement D_{n-L}, based on the slope critical acceleration a_{c-L} and a peak ground acceleration (PGA); and calculating a landslide occurrence probability P of a target landslide region based on the earthquake-induced slope displacement D_{n-L}, to complete a seismic landslide hazard assessment of the target landslide region.

9. A processing device, comprising:
a processor; and
a memory;
wherein a computer program is stored in the memory; and the processor is configured to execute the computer program to implement the assessment method of claim 1.

10. A computer-readable storage medium, wherein a plurality of instructions are stored on the computer-readable storage medium; and the plurality of instructions are configured to be loaded by a processor to implement the assessment method of claim 1.
